(19) United States
(12) Patent Application Publication
(10) Pub. No.: US 2016/0285303 A1
(43) Pub. Date: Sep. 29, 2016

(54) MODULAR SOLAR WIRELESS TRANSMISSION DEVICE

(71) Applicant: NXCONTROL SYSTEM CO., LTD., HSINCHU COUNTY (TW)

(72) Inventor: TSUNG-HSIANG MI, HSIINCHU COUNTY (TW)

(21) Appl. No.: 14/667,803

(22) Filed: Mar. 25, 2015

(51) Int. Cl. H02J 7/35; H02J 7/00; H01L 31/042; H04B 1/04; H01M 10/46; H02S 10/20

(52) U.S. Cl. CPC H02J 7/355; H01M 10/465; H02S 10/20; H01L 31/042; H04B 1/04; H02J 7/007

(57) ABSTRACT

A modular solar wireless transmission device includes a wireless transmitter and multiple sensing modules detachably and selectively connected to the wireless transmitter. The wireless transmitter has a housing, and a solar cell module and a wireless transmission and power supply module mounted inside the housing. The wireless transmission and power supply module is connected to the solar cell module and a first connection port exposed beyond the housing and connected to a second connection port of one of the sensing modules. The sensing modules can be selectively connected to the wireless transmitter to detect different signals. The wireless transmission and power supply module then wirelessly transmits the detected signals to an external controller to resolve the presence of duplicated wireless transmitters. Because of solar power generation, the modular solar wireless transmission is more compact and environmental friendly.

### BACKGROUND OF THE INVENTION

1. Field of the Invention

The present invention relates to a solar wireless communication device and, more particularly, to a modular solar wireless transmission device having at least one replaceable sensing module and wirelessly communicating with compatible devices.

2. Description of the Related Art

With reference to FIG. 6, a conventional controller is applied to measurement and control over readings of humidity, temperature or smoke of the ambient environment, such as rooms inside a house. The conventional controller is mounted on a fixed location inside each room, and has a housing 31, and a control unit 32, a sensing unit 33, and two batteries 34 mounted inside the housing 31. The conventional controller further has a keypad 35 and a display unit 36 mounted on an outer surface of the conventional controller. The control unit 32 is electrically connected to the sensing unit 33, the two batteries 34, the keypad 35, and the display unit 36. The sensing unit 33 serves to detect the readings of humidity, temperature, or smoke in the ambient environment. The two batteries 34 serve to supply power to the control unit 32. The control unit 32 adjusts a setting of humidity, temperature, or smoke previously configured for a corresponding room according to the detected readings of humidity, temperature or smoke. The keypad 35 serves to output a command to the control unit 32. The display unit 36 serves to display a currently detected reading of humidity, temperature, or smoke. When the conventional controller is intended for operation, the batteries 34 with sufficient power are mounted inside the housing 31 and are electrically connected to the control unit 32 for the control unit 32 to adjust the value of humidity, temperature, or smoke in each room.

However, the conventional controller having one sensing unit 33 can only detect the readings of one of humidity, temperature, and smoke. If users intend to detect the readings of humidity, temperature and smoke at the same time, it is necessary to provide one respective conventional controller to where detection of each of humidity, temperature, and smoke is needed. Therefore, space economy and operational convenience fails to be ensured due to the detection requirement with multiple conventional controllers.

### SUMMARY OF THE INVENTION

An objective of the present invention is to provide a modular solar wireless transmission device adopting a modular design for wireless transmission of various detected signals and solar power generation for power supply to ensure cost saving, reduced pollution, and compact size.

To achieve the foregoing objective, the modular solar wireless transmission device includes a wireless transmitter, a first connection port, and at least one sensing module.

The wireless transmitter has a housing, a solar cell module, and a wireless transmission and power supply module.

The solar cell module is mounted inside the housing.

The wireless transmission and power supply module is mounted inside the housing and serves to supply power and transmit signals.

The first connection port is electrically connected to the solar cell module and the wireless transmission and power supply module of the wireless transmitter, and protrudes beyond the housing.

Each one of the at least one sensing module has a second connection port detachably and electrically connected to the first connection port of the wireless transmitter to detect the signals and transmit the signals to the wireless transmission and power supply module of the wireless transmitter.

The foregoing modular solar wireless transmission device can repeatedly employ the wireless transmitter selectively connected to a different one of the at least one sensing module for detecting signals associated with a different one of multiple environmental conditions or fetching signals associated with images of the ambient environment. The wireless transmitter further wirelessly transmits the detected or fetched signals to a controller. Accordingly, the modular solar wireless transmission device is compatible with multiple sensing devices to achieve detection of multiple environmental conditions and wireless transmission of the detected results, thereby providing users with operational convenience and resolving the issue of duplicated wireless transmitter by simply replacing the sensing module corresponding to the desired signal detection.

Additionally, as the wireless transmitter is equipped with the solar cell module and is integrated with a flexible thin-film rechargeable battery module, the modular solar wireless transmission device acquires power from solar power generation without requiring battery purchase and replacement. Also because of the flexible thin-film rechargeable battery module, the solar cell module is more compact than regular batteries, and not only lowers users' expenditure but also ensures environmental protection for getting rid of discarded batteries.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a modular solar wireless transmission device in accordance with the present invention;

FIG. 2 is an exploded perspective view of the modular solar wireless transmission device in FIG. 1;

FIG. 3 is a cross-sectional side view of the modular solar wireless transmission device in FIG. 1;

FIG. 4 is a functional block diagram of the modular solar wireless transmission device in FIG. 1;

FIG. 5 is an operational schematic diagram of the modular solar wireless transmission device in FIG. 1; and

FIG. 6 is an exploded perspective view of a conventional controller.

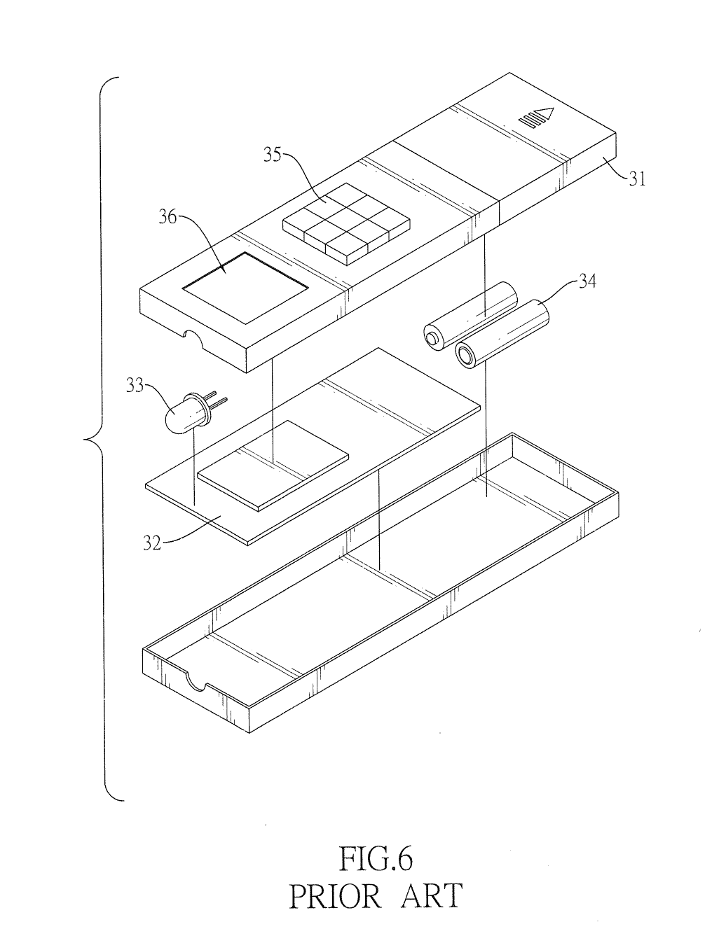

### DETAILED DESCRIPTION OF THE INVENTION

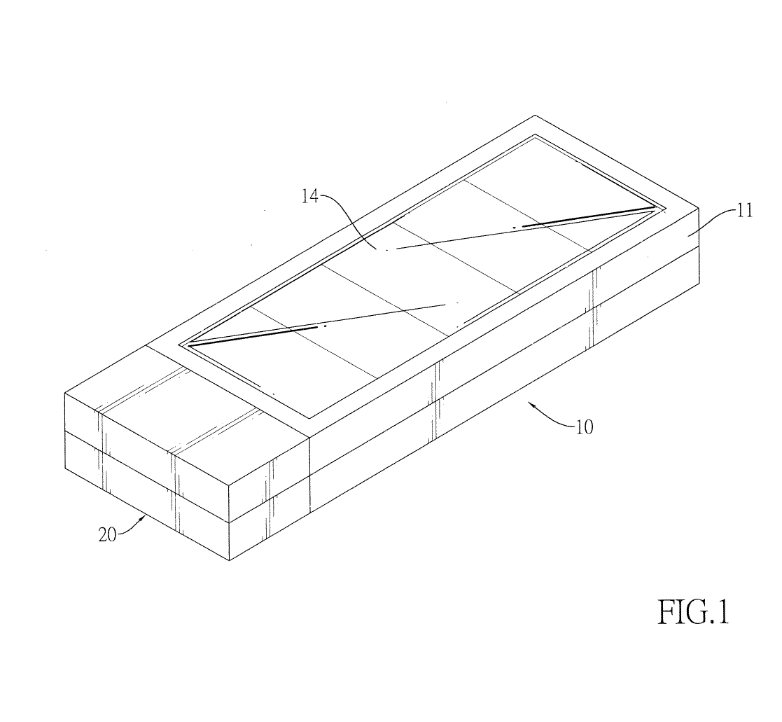

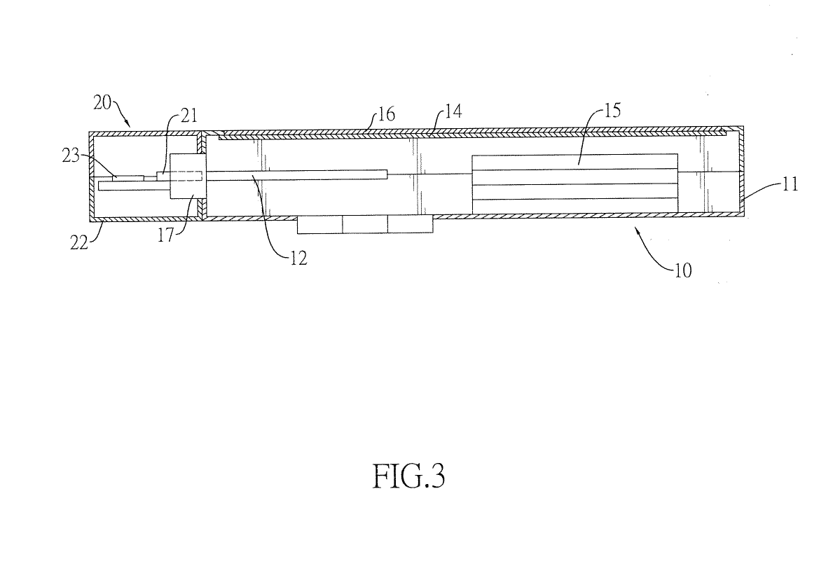

With reference to FIGS. 1 to 3, a modular solar wireless transmission device in accordance with the present invention includes a wireless transmitter 10 and at least one sensing module 20. The wireless transmitter 10 has a housing 11, a solar cell module, a wireless transmission and power supply module 12, and a first connection port 17. The solar cell module and the wireless transmission and power supply module 12 are mounted inside the housing 11.

In the present embodiment, the housing 11 is hollow, takes the form of a rectangular box, and has an opening 13 formed through a surface of the housing 11. The solar cell module is mounted inside the housing 11. The solar cell module has a solar cell 14 and a rechargeable battery 15. The rechargeable battery 15 is mounted inside the housing 11 for storing electricity generated by the solar cell 14 and supplying an operating power. The rechargeable battery 15 is formed by multiple flexible thin-film rechargeable batteries stacked to each other. The solar cell 14 is mounted inside the housing 11, is attached to an inner portion of the housing bordering the opening 13, is exposed through the opening 13, and is electrically connected to the rechargeable battery 15 to absorb energy of photons above the band gap energy in the spectrum of sunlight and charge the rechargeable battery 15 with the electricity converted from the photon energy. The solar cell 14 has a light-receiving surface.

The wireless transmission and power supply module 12 is mounted inside the housing 11 and is connected to the rechargeable battery 15 of the solar cell module. The wireless transmission and power supply module 12 wirelessly transmits signals detected by the sensing module 20 to a controller.

The first connection port 17 is electrically connected to the solar cell module and the wireless transmission and power supply module 12, and is exposed beyond the housing 11 for connection with the sensing module 20.

The housing further has a transparent protection plate 16 mounted on the housing 11 and covering the opening 13 of the housing 11 for the solar cell 14 of the solar cell module to be mounted between the transparent protection plate 16 and an inner wall of the housing 11. The transparent protection plate 16 serves to protect the solar cell 14 against damage arising from moisture permeation and collision with hard objects.

The sensing module 20 may be a temperature sensor, a humidity sensor, a smoke detector, or an image fetching device, and has a second connection port 21 electrically connected to the first connection port 17 of the wireless transmitter 10. In the present embodiment, the second connection port 21 is detachably connected to the first connection port 17. The sensing module 20 has a protection enclosure 22 and a sensing chip 23. The sensing chip 23 is mounted inside the protection enclosure 22, is electrically connected to the second connection port 21 exposed beyond the protection enclosure 22, is connected to the wireless transmission and power supply module 12 sequentially through the second connection port 21 and the first connection port 17, detects signals associated with readings of humidity, temperature or smoke in the ambient environment or signals associated with fetched images, and transmits the detected signals to the wireless transmission and power supply module 12.

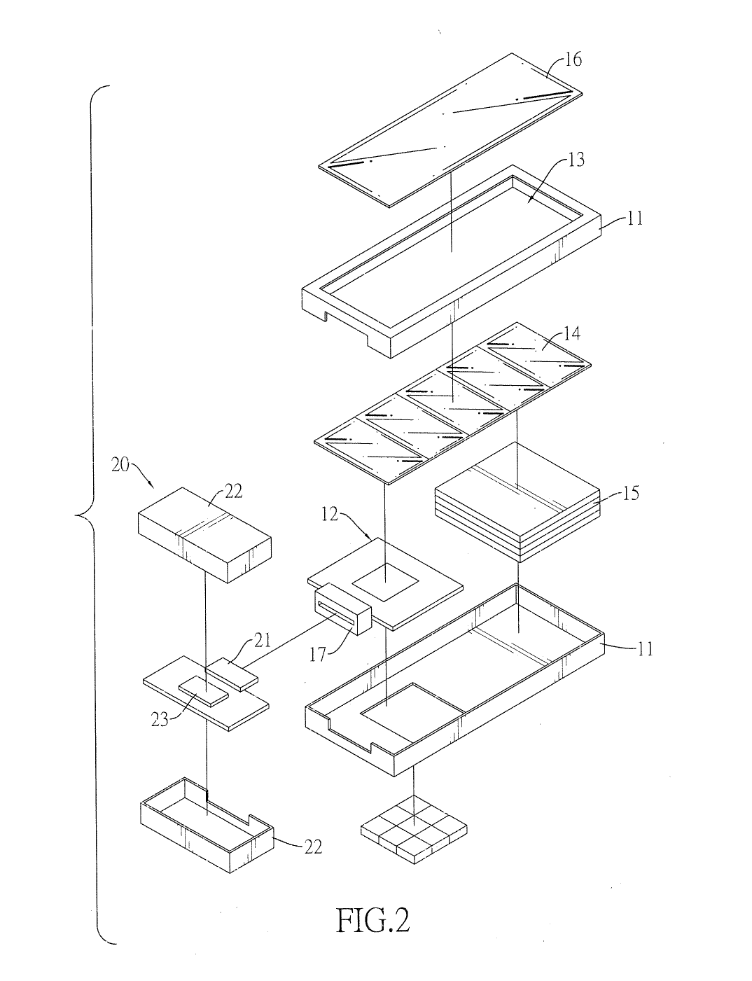

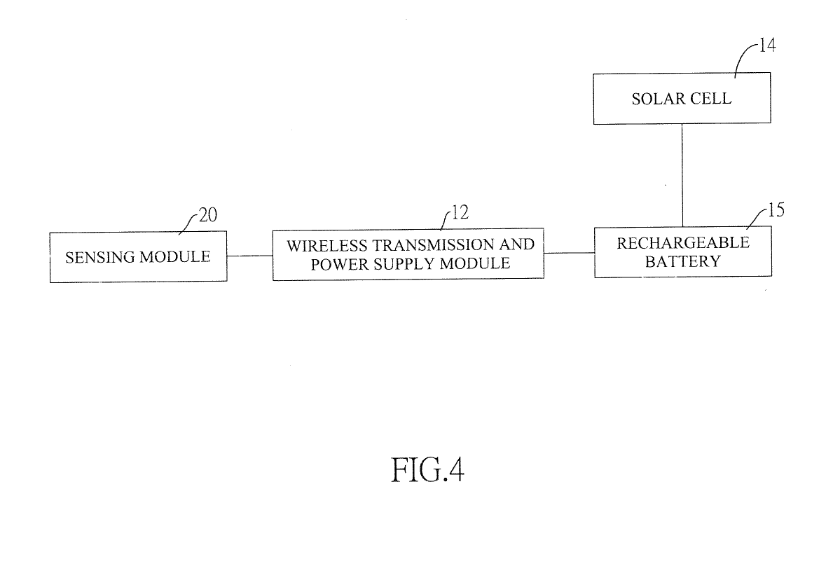

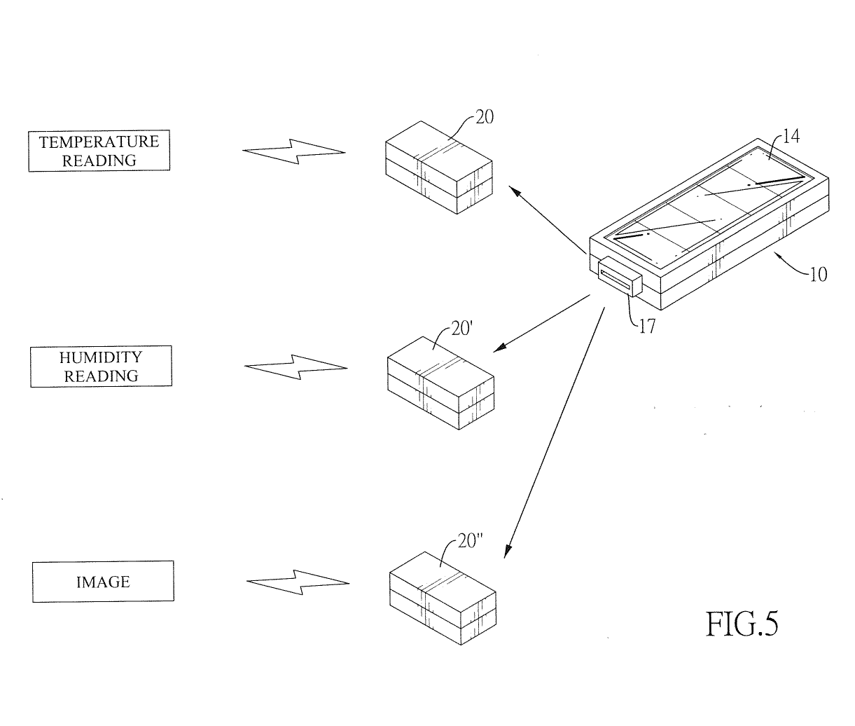

With reference to FIGS. 2 and 4, when the modular solar wireless transmission device is in use, the solar cell 14 of the solar cell module converts sunlight into electricity, stores the electricity in the rechargeable battery 15, and supplies an operating power to the wireless transmission and power supply module 12. The wireless transmission and power supply module 12 is connected to the sensing chip 23 of the sensing module 20 sequentially through the first connection port 17 and the second connection port 21 to acquire power. When the rechargeable battery 15 of the solar cell module stores sufficient power, the sensing chip 23 can detect the readings of temperature, humidity, or smoke or acquired image of the ambient environment and wirelessly transmit signals containing the detected values or acquired images to the controller through the wireless transmission and power supply module 12. With reference to FIG. 5, when users intend to detect multiple different signals of the ambient environment, such as signals associated with the readings of temperature and humidity, and signals associated with the acquired image of the ambient environment, different sensing modules 20, 20′, 20″ can be selectively mounted to the wireless transmitter 10 for the wireless transmitter 10 to wirelessly transmit the signals containing the detected readings and the acquired images of the ambient environment to the controller.

Given the foregoing modular solar wireless transmission device, the combination of the replaceable sensing module 20 and the wireless transmitter 10 allows the wireless transmitter 10 in collaboration with multiple sensing modules 20 having different functions to wirelessly transmit signals associated with different readings of environmental conditions and acquired images of the ambient environment to a controller, rendering the modular solar wireless transmission device the compatibility with various external electronic devices and the capability of transmitting multiple signals associated with different readings of environmental conditions and acquired images of the ambient environment. Accordingly, the modular solar wireless transmission device is flexible in mounting location selection and significantly lessens the concern of mounting various duplicated wireless transmitters, and what it takes is just to replace the sensing module for different sensing functions. On the other hand, the wireless transmitter 10 also has the solar cell module, meaning that the power source comes from sunlight at no additional cost for purchasing battery to reduce users' expenditure and achieve environmental protection with no production of discarded batteries, and a flexible thin-film rechargeable battery module can be employed to further reduce the size of the wireless transmitter 10.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A modular solar wireless transmission device, comprising:
a wireless transmitter having:
a housing;
a solar cell module mounted inside the housing; and
a wireless transmission and power supply module mounted inside the housing and serving to supply power and transmit signals;
a first connection port electrically connected to the solar cell module and the wireless transmission and power supply module of the wireless transmitter, and exposed beyond the housing; and
at least one sensing module, each one of the at least one sensing module having a second connection port detachably and electrically connected to the first connection port of the wireless transmitter to detect the signals and transmit the signals to the wireless transmission and power supply module of the wireless transmitter.

2. The modular solar wireless transmission device as claimed in claim 1, wherein the solar cell module has:
a solar cell; and
a rechargeable battery electrically connected to the solar cell of the solar cell module.

3. The modular solar wireless transmission device as claimed in claim 2, wherein the rechargeable battery of the solar cell module is formed by multiple flexible thin-film rechargeable batteries stacked to each other.

4. The modular solar wireless transmission device as claimed in claim 3, wherein the solar cell of the solar cell module has a light-receiving surface, and the housing further has a transparent protection plate mounted on the housing for the solar cell to be mounted between the transparent protection plate and an inner wall of the housing.

5. The modular solar wireless transmission device as claimed in claim 4, wherein the housing has an opening formed through a surface of the housing for the solar cell of the solar cell module to be exposed through the opening.

6. The modular solar wireless transmission device as claimed in claim 1, wherein each one of the at least one sensing module has:
a protection enclosure; and
a sensing chip mounted inside the protection enclosure and electrically connected to the second connection port exposed beyond the protection enclosure.

7. The modular solar wireless transmission device as claimed in claim 2, wherein each one of the at least one sensing module has:
a protection enclosure; and
a sensing chip mounted inside the protection enclosure and electrically connected to the second connection port exposed beyond the protection enclosure.

8. The modular solar wireless transmission device as claimed in claim 3, wherein each one of the at least one sensing module has:
a protection enclosure; and
a sensing chip mounted inside the protection enclosure and electrically connected to the second connection port exposed beyond the protection enclosure.

9. The modular solar wireless transmission device as claimed in claim 4, wherein each one of the at least one sensing module has:
a protection enclosure; and
a sensing chip mounted inside the protection enclosure and electrically connected to the second connection port exposed beyond the protection enclosure.

10. The modular solar wireless transmission device as claimed in claim 5, wherein each one of the at least one sensing module has:
a protection enclosure; and
a sensing chip mounted inside the protection enclosure and electrically connected to the second connection port exposed beyond the protection enclosure.

11. The modular solar wireless transmission device as claimed in claim 6, wherein each one of the at least one sensing module is one of a temperature sensor, a humidity sensor, a smoke detector, and an image fetching device.

12. The modular solar wireless transmission device as claimed in claim 7, wherein each one of the at least one sensing module is one of a temperature sensor, a humidity sensor, a smoke detector, and an image fetching device.

13. The modular solar wireless transmission device as claimed in claim 8, wherein each one of the at least one sensing module is one of a temperature sensor, a humidity sensor, a smoke detector, and an image fetching device.

14. The modular solar wireless transmission device as claimed in claim 9, wherein each one of the at least one sensing module is one of a temperature sensor, a humidity sensor, a smoke detector, and an image fetching device.

15. The modular solar wireless transmission device as claimed in claim 10, wherein each one of the at least one sensing module is one of a temperature sensor, a humidity sensor, a smoke detector, and an image fetching device.

16. The modular solar wireless transmission device as claimed in claim 6, wherein the sensing chip of each one of the at least one sensing module is connected to the wireless transmission and power supply module sequentially through the second connection port and the first connection port to detect the signals, and transmits the signals to the wireless transmission and power supply module for the wireless transmission and power supply module to wirelessly transmit the signals.

17. The modular solar wireless transmission device as claimed in claim 7, wherein the sensing chip of each one of the at least one sensing module is connected to the wireless transmission and power supply module sequentially through the second connection port and the first connection port to detect the signals, and transmits the signals to the wireless transmission and power supply module for the wireless transmission and power supply module to wirelessly transmit the signals.

18. The modular solar wireless transmission device as claimed in claim 8, wherein the sensing chip of each one of the at least one sensing module is connected to the wireless transmission and power supply module sequentially through the second connection port and the first connection port to detect the signals, and transmits the signals to the wireless transmission and power supply module for the wireless transmission and power supply module to wirelessly transmit the signals.

19. The modular solar wireless transmission device as claimed in claim 9, wherein the sensing chip of each one of the at least one sensing module is connected to the wireless transmission and power supply module sequentially through the second connection port and the first connection port to detect the signals, and transmits the signals to the wireless transmission and power supply module for the wireless transmission and power supply module to wirelessly transmit the signals.

20. The modular solar wireless transmission device as claimed in claim 10, wherein the sensing chip of each one of the at least one sensing module is connected to the wireless transmission and power supply module sequentially through the second connection port and the first connection port to detect the signals, and transmits the signals to the wireless transmission and power supply module for the wireless transmission and power supply module to wirelessly transmit the signals.

21. The modular solar wireless transmission device as claimed in claim 6, wherein the housing takes a form of a rectangular box.

22. The modular solar wireless transmission device as claimed in claim 7, wherein the housing takes a form of a rectangular box.

23. The modular solar wireless transmission device as claimed in claim 8, wherein the housing takes a form of a rectangular box.

24. The modular solar wireless transmission device as claimed in claim 9, wherein the housing takes a form of a rectangular box.

25. The modular solar wireless transmission device as claimed in claim 10, wherein the housing takes a form of a rectangular box.
